(19) United States
(12) Patent Application Publication
(10) Pub. No.: US 2023/0361696 A1
(43) Pub. Date: Nov. 9, 2023

(54) ENERGY HARVESTING AND STORAGE FEEDBACK CELL

(71) Applicant: Universidade Do Porto, Porto (PT)

(72) Inventor: Maria Helena SOUSA SOARES DE OLIVEIRA BRAGA, Porto (PT)

(21) Appl. No.: 18/245,734

(22) PCT Filed: Sep. 20, 2021
(86) PCT No.: PCT/IB2021/058551

§ 371 Date: Mar. 17, 2023

(30) Foreign Application Priority Data
Sep. 18, 2020 (PT) 116750

(51) Int. Cl. H02N 11/00; H10N 60/00

(52) U.S. Cl. CPC H02N 11/008; H10N 60/99

(57) ABSTRACT

Disclosed is a kinetic energy harvest and electrical energy storage feedback cell that combines the 2-dimensional superconductor behaviour induced by a ferroelectric-metal with a quantum. Hall Effect placed within two conductor/semiconductor materials with different chemical potentials. The feedback corresponding to external and internal conduction and tunnelling of the electrons in the cell allows the electrical potential difference to increase during discharge of the cell with a load. The feedback cell harvests kinetic energy, heat and store electrostatic and electrochemical energy that at room temperature the supercurrent can be induced during several years in feedback and can be used as part of a transistor, a computer, a photovoltaic cell or panel, a wind turbine, a vehicle, a ship, a satellite, an airplane, a remote access circuit, a building, smart grid, electric power transmission, transformers, power storage devices, electric motors and as a part of other several components or products.

### TECHNICAL FIELD

The present invention is a kinetic energy harvest and electrical energy storage feedback cell that combines the 2-dimensional (2D) superconductor behaviour induced by a ferroelectric-metal with a quantum Hall Effect spontaneously induced around the surface and interfaces with the two electrodes. Independently, to align the chemical potentials between the ferroelectric and the electrodes, Electrical Double Layer Capacitors (EDLCs) are formed at the interfaces. The ferroelectric-metal polarization and the alignment of the charges at the EDLCs are not screened by the 2D fast electron current and the ferroelectric-metal remains polarized. When the cell is set to discharge with a load and the chemical potential of the positive electrode becomes equal to the ferroelectric's, the electrons accumulated at the ferroelectric interface are conducted through the surface to the electrical negative capacitance Double Layer Capacitor (EDL-C′) at the interface with the negative electrode. From the EDL-C′ at the interface with the negative electrode, the electrons tunnel to the negative electrode resulting in the increase of its chemical potential, and consequently of the potential difference across the cell, while discharging with a load. This process is not observed in other discharges of energy storage cells, such as traditional batteries, and configures a harvesting process in a storage cell at a constant temperature. This process repeats as the electrons are discharged through the external circuit and recovered on the positive electrode, tunnelling to the surface of the ferroelectric. This feedback circuit involving the conduction of electrons through the interior and exterior of the cell, as in two Poincaré maps, shapes a harvesting and storage cell supported by the kinetic energy of ions and dipoles in the ferroelectric, and its surface fast conducting electrons. It is not dependent on a gradient or on a temperature fluctuation. It works at constant temperature, but it can be enhanced by a temperature gradient or fluctuation.

### BACKGROUND

A Superconductor is a material capable of showing a zero electrical resistance; electrical superconductivity it is, therefore, a property related with electrons. Bulk superconductors are also able to maintain a current with no applied voltage, a property exploited in superconducting electromagnets such as those found in MRI machines. Experiments have demonstrated that currents in superconducting coils can persist for years without any degradation. Several materials have been reported to show bulk superconductivity, like Be, Ti, Zr, Zn, Sn, at low temperatures and the high-temperature cuprate superconductors, like HgBa₂Ca₂Cu₃Oₓ or the iron based FeSe. The highest temperature superconductor is H₂S but it also requires high pressure.

A Superconductor enables, therefore, the transmission of electrical power without any loss and exhibits no heat dissipation (no Joule effect). The development of novel architectures for harvesting and subsequently storing energy brings important benefits to humankind.

A Ferroelectric material is a material that polarizes spontaneously and whose polarization can be reversed by the application of an external electric field. All Ferroelectrics are Pyroelectrics, their natural electrical polarization is reversible.

Ferroelectrics with extremely high dielectric constant like Li_{3-2y}M_{y}ClO (M=Be, Ca, Mg, Sr, and Ba), Li_{3-3y}A_{y}ClO (M=B, Al), Na_{3-2y}M_{y}ClO (M=Be, Ca, Mg, Sr, and Ba), Na_{3-3y}A_{y}ClO (M=B, Al), K_{3-2y}M_{y}ClO (M=Be, Ca, Mg, Sr, and Ba), K_{3-3y}A_{y}ClO (M=B, Al) or antiperovskites (crystalline materials) like Li_{3-2y-z}M_{y}H_{z}ClO (M=Be, Ca, Mg, Sr, and Ba), Li_{3-3y-z}A_{y}H_{z}ClO (M=B, Al), Na_{3-2y-z}M_{y}H_{z}ClO (M=Be, Ca, Mg, Sr, and Ba), Na_{3-3y-z}A_{y}H_{z}ClO (M=B, Al), K_{3-2y-z}M_{y}H_{z}ClO (M=Be, Ca, Mg, Sr, and Ba), K_{3-3y-z}A_{y}H_{z}ClO (M=B, Al), a mixture of thereof or a mixture of thereof with Li₂S, Na₂S, K₂S, Li₂O, Na₂O, K₂O, SiO₂, Al₂O₃, or H₂S or a mixture of thereof with a polymer forming a composite, can become a surface (2D) superconductor. This condition does not require being a bulk superconductor as defined above in the first paragraph of the background.

A Thermoelectric cell or Generator (TEG) is constituted by a heat source and a heat sink separated by the thermoelectric material (TE) and a collector. Usually, the cell is constituted by two different TEs (an n-semiconductor and a p-semiconductor) to allow electrons (in n-semiconductor) and holes (in p-semiconductor) to be conducted from the hot source to the hot sink. The working principle of TEGs depends on a temperature difference and a gradient, J=−σS∇T, where J is the current density, tithe electrical conductivity, S=ΔV/ΔT the Seebeck coefficient, ΔV the potential difference across the material when a temperature difference ΔT is applied, and ∇T the temperature gradient. Thermoelectric materials have demonstrated their ability to directly convert thermal into electrical energy via the Seebeck effect.

The Thermoelectric performance (for either power generation or as a heat pump in which electricity can drive a Peltier cooler) depends on the efficiency of the Thermoelectric material for transforming heat into electricity. The efficiency of a Thermoelectric material depends primarily on the Thermoelectric materials figure-of-merit, known as zT, zT=S²σT/κ, where κ is the thermal conductivity. It is not straightforward to find a n- and p-semiconductor pair that can be used near room temperature. The latter difficulty is identified as one of the problems in classic TEs and the others are related to obtaining a high electrical conductivity (σ), or low resistivity (ρ), while obtaining a high thermal conductivity (κ). Finally, the requirements partially translate into finding a semiconductor TE with a charge carrier concentration that is about 10²⁰ cm⁻³. This ‘ideal’ concentration of charge carriers is found associated with TE topological phenomena and, independently, with 2D superconductivity in polar-metals such as certain ferroelectrics.

In the 1950s, the milestone concepts of narrow bandgap semiconductors and solid solutions led to the discovery of (Bi,Sb)₂(Te,Se)₃ and Bi₁₋ₓSbₓ TE systems, which have become the most successful TE materials for power generation and refrigeration near and below room temperature. The latest major advance started in the 1990s, and its development continues to date based on the novel ideas of low-dimensionality (2D), ‘phonon-glass electron-crystal’ paradigm electronic structure engineering, hierarchical phonon scattering, and point defect engineering.

Pyroelectricity is a phenomenon in which temperature fluctuations applied to a pyroelectric material induce a change in polarization, which further causes the separation of bound charges. The term “temperature fluctuation” refers to the dynamic condition where temperature varies with time (e.g. oscillations). As such, pyroelectricity can result in an alternating current (AC). The pyroelectric phenomena depend, therefore, on a dynamic variation of the temperature expressed by, I=A(dPs/dT)(dT/dt), where I is the harvested current, A is the surface area, Ps is the spontaneous polarization, and T is the temperature.

Surface 2D superconductivity is established in polar materials such as ferroelectric semiconductors. It is observed, in particular, in polar metal/insulator heterojunctions typically at low-temperatures (<50 K) where the polar material is a superconductor with dielectric constant εᵣ>103, converting the latter into ferroelectric “metals” with surface superconductivity.

Negative capacitance is related with topological (2D) phenomena and associated with processes conducing to local 2D superconductivity which subsequently, fed by excitations, may result in electron tunnelling.

### SUMMARY OF THE INVENTION

The present invention is directed to a feedback cell using a ferroelectric-induced 2D superconductor that performs from below to above room temperatures.

The present invention is directed to a feedback cell in which the electrical potential difference available increases during discharge of the cell with a load.

The present invention is directed to a feedback cell in which the charge may be obtained just by the relaxation of the cell.

The present invention is directed to a feedback cell in which the thermoelectric phenomena can potentiate the output power.

The present invention is directed to a feedback cell in which the pyroelectric phenomena can potentiate the output power.

The present invention is directed to a feedback cell that can harvest kinetic energy.

The present invention is directed to a feedback cell that can harvest heat.

The present invention is directed to a feedback cell that can store electrostatic and electrochemical energy.

The present invention is directed to a feedback cell in which electrons are feedback into the circuit in one electrode and conducted through the surface of the ferroelectric electrolyte, tunnelling back to the other electrode increasing the chemical potential, and the electrical potential difference across the cell where the electrical potential difference is spontaneously expected to decrease.

The present invention discloses a feedback cell comprising a high dielectric constant ferroelectric 2D superconductor or ferroelectric-metal placed between two similar or dissimilar materials wherein the electrical potential difference of the cell increases during discharge with a load from below to above room temperatures.

Furthermore, the invention reveals the feedback cell in which the ferroelectric comprises the materials, R_{3-2y}M_{y}Cl₁₋ₓHa₁₋ₓO_{1-z}A_{z} with (R=Li, Na, K; M=Be, Ca, Mg, Sr, and Ba; Hal=F, Br, I; A=S, Se) and 0≤y≤0.5, 0≤x≤1, and 0≤z≤1, R_{3-3y}M_{y}Cl₁₋ₓHa₁₋ₓO_{1-z}A_{z} with (R=Li, Na, K; M=B, Al; Hal=F, Br, I; A=S, Se) and 0≤y≤0.5, 0≤x≤1, and 0≤z≤1, R_{3-2y-z}M′_{y}H_{z}Cl₁₋ₓHalₓO_{1-d}A_{d} (R=Li, Na, K; M′=Be, Ca, Mg, Sr, and Ba; Hal=F, Br, I; A=S, Se) and 0≤y≤0.5, 0≤z≤2, 0≤x≤1, and 0≤d≤1, R_{3-3y-z}M′_{y}H_{z}Cl₁₋ₓHalₓO_{1-d}A_{d} with 0≤y≤0.5, 0≤z≤2, 0≤x≤1, and 0≤d≤1, a mixture of thereof or a mixture of thereof with Li₂S, Na₂S, SiO₂, Li₂O, Na₂O, or H₂S or a mixture thereof with a polymer, a plasticizer, or a glue.

Additionally, the ferroelectric-metal of the feedback cell can be in contact with one or two insulator layers, such as air or vacuum.

Moreover, the feedback cell containing a ferroelectric-metal, comprising two interfaces with two similar or dissimilar conductors.

The present invention also discloses the feedback cell in which ferroelectric-metal, comprising two interfaces with two similar or dissimilar insulators.

The feedback cell can present a further configuration in that the ferroelectric can be the Na-based Na_{2.99}Ba_{0.005}ClO and the conductors are Cu.

The feedback cell can present a further configuration in that the ferroelectric is the Na-based Na_{2.99}Ba_{0.005}ClO and the conductors are Zn and Cu.

Additionally, the feedback cell where the ferroelectric is the Na-based Na_{2.99}Ba_{0.005}ClO and the conductors are Zn and C foam, sponge, wires, nanotubes, graphene, graphite, carbon black or any other allotrope or carbon structure, with or without impurities.

Moreover, the feedback cell where the ferroelectric is the Li-based (1-x)Li_{2.99}Ba_{0.005}ClO+xLi_{3-2y-z}M_{y}H_{z}ClO, with 0≤x≤1, one conductor is Li and the other is a mixture of MnO₂ with carbon black and a binder.

The feedback cell can present a further configuration in that the ferroelectric is the Na-based (1-x)Na_{2.99}Ba_{0.005}ClO+xNa_{3-2y-z}M_{y}H_{z}ClO, with 0≤x≤1 and 0≤z≤2, one conductor is Na and the other is a mixture of Na₃V₂(PO₄)₃ with carbon black and a binder.

The feedback cell can comprise two interfaces with two similar or dissimilar semiconductors or a conductor and a semiconductor.

The feedback cell can present a further configuration in that the ferroelectric is the Li-based Li_{2.99}Ba_{0.005}ClO+Li₂S, the conductor is Al and the semiconductor Si.

The feedback cell can present a further configuration in that the ferroelectric is the Li-based Li_{2.99}Ba_{0.005}ClO+Li_{3-2y-z}M_{y}H_{z}ClO, with 0≤y≤1 and 0≤z≤2, the conductor is Li and the semiconductor MnO₂ or a mixture of sulfur and carbon.

The feedback cell can comprise two interfaces one a semiconductor or a conductor, and the other an insulator with a conductor contact or electron collector.

The feedback cell can present a further configuration in that the ferroelectric is the Na-based, K-based, or Li-based and the conductors are Zn or Cu, Li, Na, a Li alloy or composite, a Na alloy or composite, a K alloy or a composite. The ferroelectric surface area is in contact with an insulator such as air, vacuum, polymer, plasticizer, insulating tape, glue, or binder.

The feedback cell can present a further configuration in that the ferroelectric is Li-based, Li_{2.99}Ba_{0.005}ClO or a Li_{2.99}Ba_{0.005}ClO+Li_{3-2y-z}M_{y}H_{z}ClO mixture or a composite, and the conductor is Li or a Li alloy such as the solid solution of Mg in lithium. The ferroelectric surface area is in contact with an insulator such as air, vacuum, polymer, plasticizer, ionic liquid, insulating tape, glue, or binder.

The feedback cell can comprise two concentric wire conductors separated by a ferroelectric.

The feedback cell can comprise at least one interface between a ferroelectric and an insulator.

The feedback cell can present a further configuration in that the insulator is SiO₂, a polymer, a plasticizer such as succinonitrile, air.

The feedback cell can comprise at least one interface between a ferroelectric and a superconductor.

The feedback cell can present a further configuration in that the superconductor is ZnO.

The feedback cell can present a further configuration in that the ferroelectric is Li, K, or Na-based and the superconductors are both Al or Ti or Sn, Li and Al, or Li and Ti or Sn.

The feedback cell can present a further configuration in that the ferroelectric is Li, K, or Na-based and the superconductors are HgBa₂Ca₂Cu₃Oₓ FeSe, or H₂S.

The feedback cell can present a further configuration in that the ferroelectric is a composite such as a ferroelectric polymer-glue mixture or a ferroelectric ionic liquid mixture.

The feedback cell can present a further configuration in that the ferroelectric is CaCuTiO₃ or a composite or a mixture of the ferroelectric materials listed above.

The feedback cell can perform at constant temperature.

The feedback cell can perform under a gradient temperature, such as in a thermoelectric generator, from −15 to 250° C.

The feedback cell can perform under a variable temperature, a temperature fluctuation, such as a pyroelectric generator, from −15 to 250° C.

Use of the feedback cells described above as an energy harvester.

Use of the feedback cells described above as an energy harvester and energy storage device.

Use of the feedback cells described above as a part of a transistor, a computer, a photovoltaic cell or panel, a wind turbine, a vehicle, a ship, a satellite, an airplane, a remote access circuit, a building, a smart grid, electric power transmission, transformers, power storage devices, or electric motors.

### DESCRIPTION OF THE DRAWINGS

These and other features, aspects and advantages of the present invention will become better understood with reference to the following description and appended claims, and accompanying drawings wherein.

FIG. 1 is the embodiment of a conductor1/Na-based ferroelectric composite/conductor2 feedback cell set to discharge at 40° C. with a 2000Ω external and material resistor. There were ten potential difference boosts proceeded by mild increments of the potential difference in approximately 450 h of discharge experiment;

FIG. 2 is the embodiment of a conductor1/Na-based ferroelectric composite/conductor2 feedback cell set to discharge at 50° C. with a 1000Ω an external resistor. It is observed an example of the oscillation phenomena typical of this embodiment usually taking place before and after the boost in chemical potential of the negative electrode leading to a boost in the potential difference of the cell, while the cell is set to discharge.

FIG. 3 is the embodiment of a conductor1/ferroelectric-metal composite/conductor2 feedback cell in that after being set to discharge showing similar behaviour as a traditional cell;

FIG. 4 is the embodiment of a conductor1/ferroelectric-metal/conductor2 feedback cell while feedback happens in the cell and electrons travel from conductor2 to conductor1 through the surface of the ferroelectric-metal;

FIG. 5 is the embodiment of a conductor1/ferroelectric-metal/conductor2 feedback cell during discharge while feedback happens at the quantum level with tunnel of electrons back and forth to the conductor1 and the ferroelectric;

FIG. 6 is the embodiment of a conductor1/ferroelectric-metal/conductor2 feedback process at constant temperature (above) and using the cell as a thermoelectric device (below). Below, on the right side, photographs with an embodiment of the combined feedback, thermoelectric and pyroelectric effects;

FIG. 7 is the embodiment of a conductor/ferroelectric/conductor feedback process while the cell is set to discharge;

FIG. 8 is another embodiment of a conductor/ferroelectric/semiconductor feedback process while the cell is set to discharge;

FIG. 9 is another embodiment of a semiconductor/ferroelectric/semiconductor feedback process while the cell is set to discharge;

FIG. 10 is another embodiment of a superconductor/ferroelectric/superconductor feedback process while the cell is set to discharge;

FIG. 11 is the embodiment of a conductor/ferroelectric/conductor feedback process while the cell is set to discharge showing an embodiment of the double layer capacitor and negative double layer capacitor at the conductor/ferroelectric interface.

### DESCRIPTION OF THE INVENTION

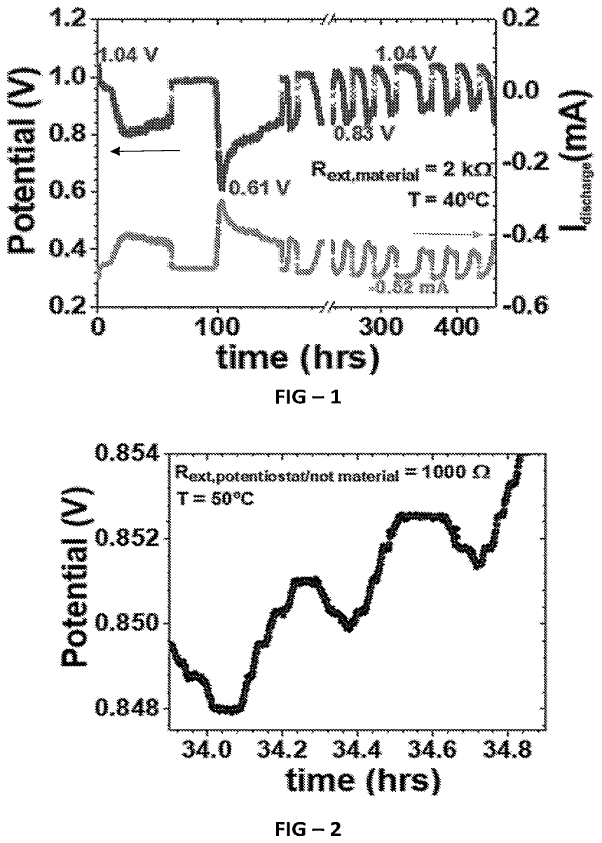

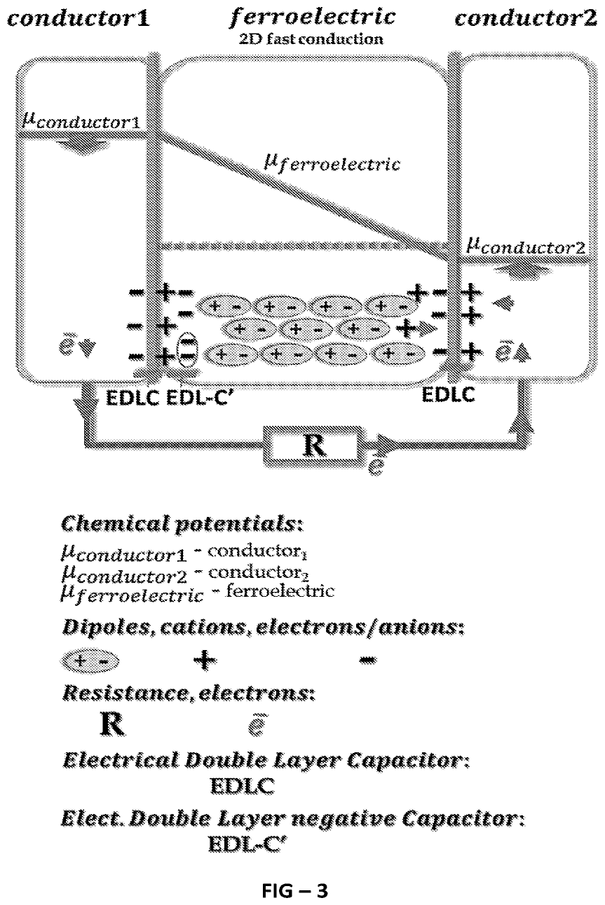

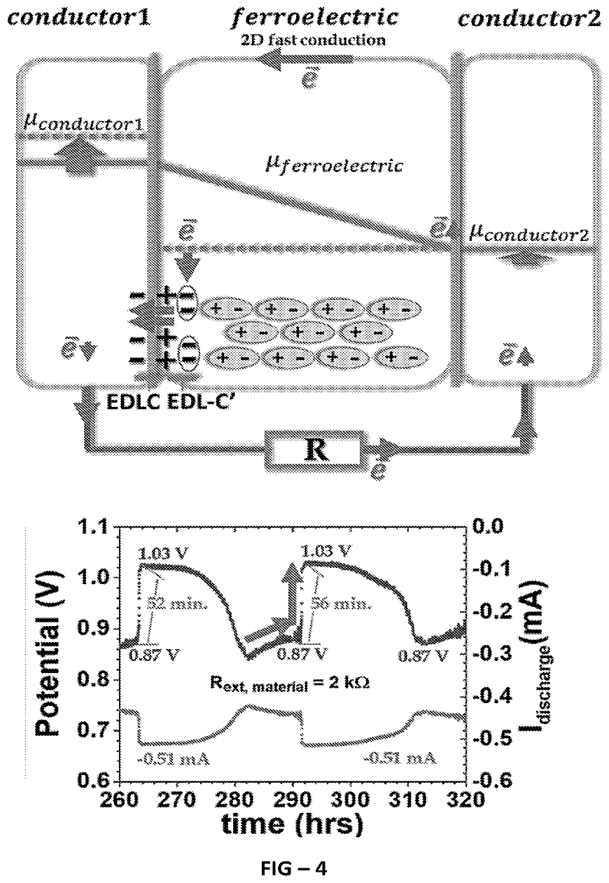

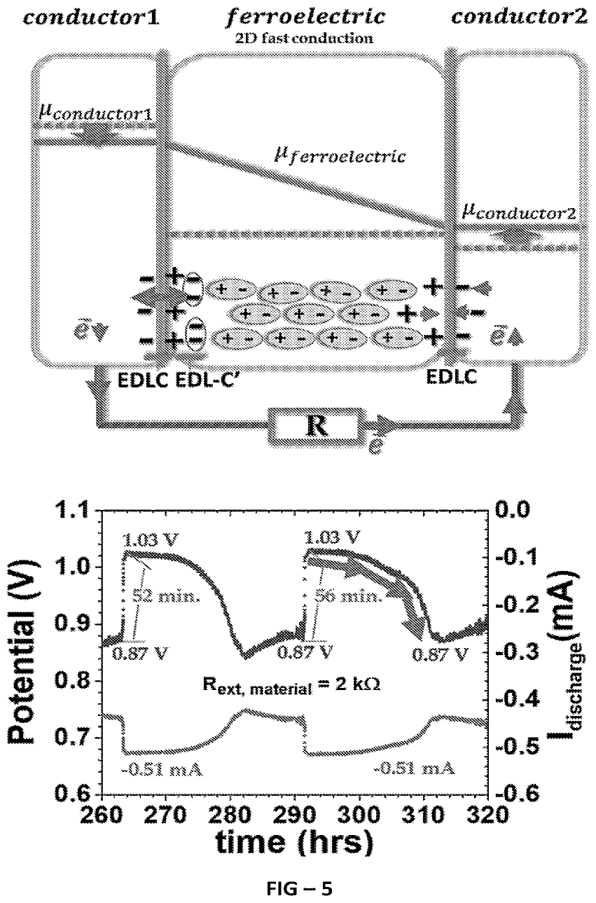

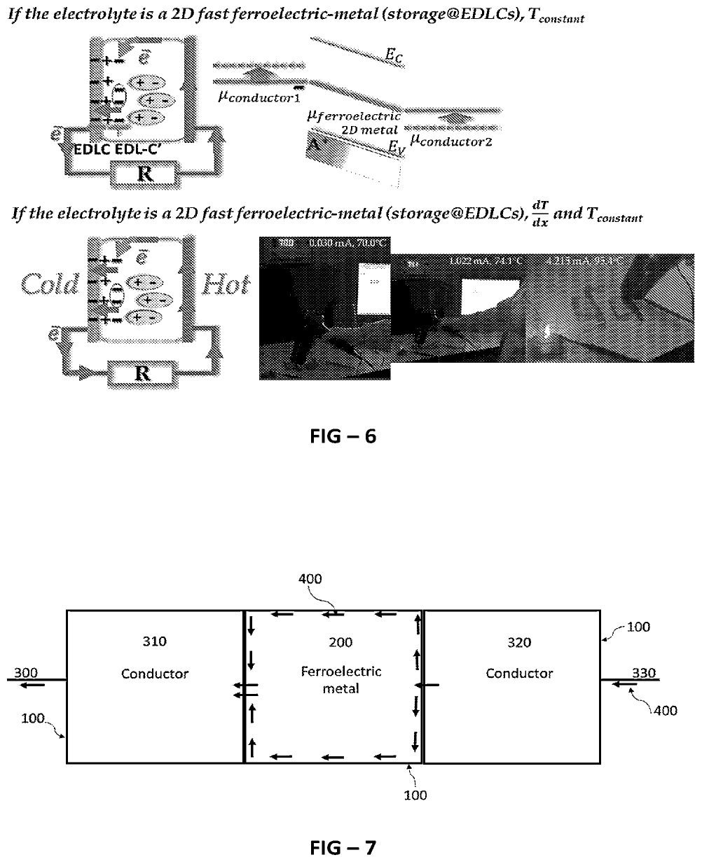

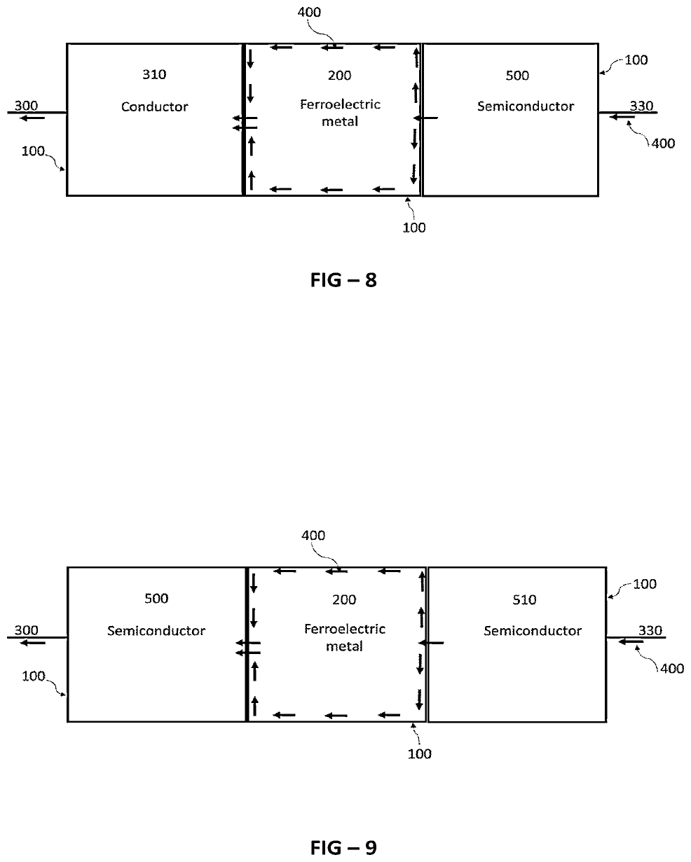

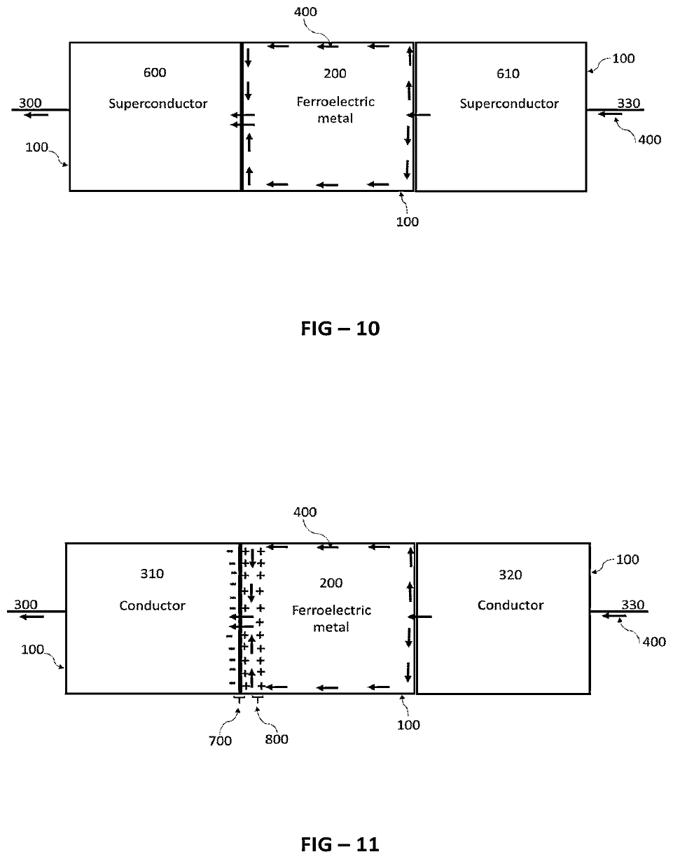

The preferred embodiments of the present invention are illustrated by way of example below and in FIGS. 1-11. As shown in FIG. 1 the feedback process in an embodiment containing a conductor 1, a ferroelectric-metal and a conductor2 consisting in a slow charge from a potential difference (>=0.61 V) or (>=0.80 V) to (0.84 V) or (0.92 V) while showing an oscillating tunnelling effect embodiment as described in FIG. 2. Then a step increase of the potential difference from (>=0.80) to (0.99 V) or (1.04 V) takes place by the tunnelling of electrons from the ferroelectric to the conductor1 while discharging the feedback cell with a load (2,000Ω). In this embodiment the tunnelling of electrons is >=10¹⁷ cm⁻³ for a typical number of 10²⁰ cm⁻³. As shown in FIG. 2, before and after a step increase in the potential difference across the feedback cell, for example of 0.2 V, a tunnelling back and forward resulting in an oscillation of electrons from and to the ferroelectric and conductor1 happens. These oscillations have an amplitude for example of 2 mV. In this embodiment the number of tunnelling-oscillating electrons (nₑ) are 10¹⁶<=nₑ<10¹⁷ cm⁻³. As shown in FIG. 3, the feedback cell corresponding to the embodiment of FIG. 1 starts discharging as an energy storage cell; the non-magnetic Hall effect is highlighted by the accumulation of A⁺ cations at the interface with the conductor1 and electrons at the interface with conductor2. As shown in FIG. 4, the feedback cell corresponding to the embodiment of FIG. 1, starts to feedback the electrons from conductor2 to conductor1 through the surface of the ferroelectric-metal. As the chemical potential of conductor2 (μ_{conductor2}) and the chemical potential of the ferroelectric-metal (μ_{ferroelectric}) become equal, no electrons are needed to align the correspondent electrochemical potentials, and the EDLC at the ferroelectric/conductor2 is spontaneously eliminated. As shown in FIG. 5, the feedback cell, Zn/Na-glass ferroelectric composite/C+Cu, corresponding to the embodiment of FIG. 1 starts to discharge as the chemical potential of conductor2 (μ_{conductor2}) is equal or higher than the chemical potential of the ferroelectric-metal (μ_{ferroelectric}), μ_{conductor2}>=μ_{ferroelectric}. The plateau corresponds to the equilibrium between two phases, such as, Na (or a phase rich in sodium) and a phase rich in C or Cu. The embodiment shown in FIG. 4, is the feedback cell corresponding to the embodiment in FIG. 6, at constant temperature (with no temperature gradient). The variation of the chemical potentials resulting from the 2D fast conduction and tunnelling of the electrons, the accumulation of mobile ions (A⁺), the highest energy of the valence band (Eᵥ), and the lowest energy of the conduction band (E_{c}) are shown. Also shown in FIG. 6 is the feedback process but with the superposition of a thermoelectric and a pyroelectric phenomenon. Under the effect of this superposition, the output current of this embodiment increases from 0.030 to 4.215 mA, while two feedback cells in series are set to discharge with four LEDs associated in parallel and the temperature of one of the feedback cells increases from 70 to 95.4° C. As shown in FIG. 7, the feedback cell includes an insulator protection of the cell 100, a ferroelectric 200 that, at a certain temperature, behaves as a ferroelectric-metal (2D superconductor), two conductors 310 and 320, which are similar or dissimilar, two conductors 300 and 330, which are similar or dissimilar and may or may not be wires that connect to the external circuit, and electrons that are conducted in the direction of 400. As shown in FIG. 8, the feedback cell includes an insulator protection of the cell 100, a ferroelectric 200 that, at a certain temperature, behaves as a ferroelectric-metal (2D superconductor), a conductor 310 and a semiconductor 500, two conductors 300 and 330, which are similar or dissimilar and may or may not be wires that connect to the external circuit, and electrons that are conducted in the direction of 400. As shown in FIG. 9, the feedback cell includes an insulator protection of the cell 100, a ferroelectric 200 that, at a certain temperature, behaves as a ferroelectric-metal (2D superconductor), two semiconductors 500 and 510, which are similar or dissimilar, two conductors 300 and 330, which are similar or dissimilar and may or may not be wires, and electrons that are conducted in the direction of 400. As shown in FIG. 10, the feedback cell includes an insulator protection of the cell 100, a ferroelectric 200 that, at a certain temperature, behaves as a ferroelectric-metal (2D superconductor), two superconductors 600 and 610, which are similar or dissimilar, two conductors 300 and 330, which are similar or dissimilar and may or may not be wires that connect to the external circuit, and electrons that are conducted in the direction of 400. As shown in FIG. 11, the feedback cell includes an insulator protection of the cell 100, a ferroelectric 200 that, at a certain temperature, behaves as a ferroelectric-metal (2D superconductor), two conductors 310 and 320, which are similar or dissimilar, two conductors 300 and 330, which are similar or dissimilar and, may or may not, be wires that connect to the external circuit, electrons that are conducted in the direction of 400, and an electrical double layer capacitor EDLC, 700, and an electrical negative double layer capacitor EDL-C′, 800. Feedback cells of 10, 20, 40, 50, 60, 70, and 80, may or may not show EDLC and EDL-C′ as 90.

In the description of the present invention, the invention will be discussed in a laboratory environment; however, this invention can be utilized for any type of applications requiring the devices 10, 20, 30, 40, 50, 60, 70, 80, and 90.

The ferroelectric material polarizes spontaneously below the Curie temperature (ferroelectric-paraelectric phase transition), and therefore, it does not depend on a temperature fluctuation or a temperature gradient to polarize giving rise to a potential difference across its ends. The potential difference ΔV=f(P) where f(P) is a non-linear function of the polarization P in which there is an indirect dependence on the temperature at the parameter level related to the dielectric constant or relative real permittivity. The ferroelectric has the ability to switch the direction and magnitude of the spontaneous polarization by reversing the applied coercive electric field, which makes it a good candidate to be used in an energy storage device as a dielectric and/or electrolyte. A ferroelectric is also piezoelectric (polarizes in response to applied mechanical stress), and a Pyroelectric. Materials that exhibit high pyroelectric coefficients are typically ferroelectric.

A key step in the superconductor phenomena is the pairing between electrons or the formation of Cooper pairs. Despite the strong Coulomb repulsion in free space, at low energy, electrons experience an effective attraction in the presence of a lattice. Thus, superconductivity essentially relies on a mechanism that simultaneously reduces the Coulomb repulsion and generates a strong attractive interaction. In simple (elemental) metals, such an attraction originates from the interchange of longitudinal phonons, which couple to the electronic density. To allow this attraction to overcome the Coulomb repulsion, however, the phonons must be much slower than the electronic motion. In terms of energy scales, this requirement implies that the Fermi energy is much larger than the Debye energy. In the intermediate frequency regime, between these two scales, the Coulomb repulsion is logarithmically suppressed, while the phonon interaction is unaffected. As a result, the net interaction between electrons may become attractive below the Debye energy.

There are two parameters that will affect 2D superconductivity. The parameters include temperature, and current density. For a cooperative motion of electrons, the control of this motion via the coalescence and alignment of the dipoles constituting the ferroelectric material may lead to the achievement of room temperature 2D superconductivity, especially if charged matter is inhomogeneous. Presently, it is believed that the mechanism of superconductivity can be induced either by bipolarons or Cooper pairing.

A bipolaron can be defined, but without limitation, as a bosonic quasiparticle consisting of two polarons.

A polaron is a fermionic quasiparticle used in condensed matter physics to understand the interactions between electrons and atoms in a solid material.

The polaron concept was firstly introduced by Landau to describe an electron moving in a dielectric crystal where the atoms move from their equilibrium positions to effectively screen the charge of an electron, known as a phonon cloud. This lowers electron mobility and increases the electron's effective mass.

A Cooper pair or BCS pair is a pair of electrons bound together at low temperatures. An arbitrarily small attraction between electrons in a metal can cause a paired state of electrons to have a lower energy than the Fermi energy, which implies that the pair is bound. In conventional (BCS) superconductors, this attraction is due to the electron-phonon interactions. The important understanding is that independent of physical mechanism, the key to observed superconductivity is the strong electron-lattice (phonon) coupling. Strong electron-lattice interactions can be obtained from the formation of an EDLC and an EDL-C′ where the electrons are restrained by two positively charged layers of A⁺ cations or positively charged dipoles, providing justification for a ferroelectric-induced 2D superconductivity enablement.

Control of the electronic motion via coalescence and alignment of the dipoles, constituting a ferroelectric material, may also lead to the formation of pairs of electrons, or better bipolarons, contributing to the achievement of room temperature superconductivity, namely 2D-superconductivity.

A requirement for superconductivity, namely the enablement of macroscopic quantum coherence is best described by the conventional BCS (Bardeen, Cooper, and Schrieffer) theory. As the current flows, for example, along the surface of ferroelectric 200, positive ions or dipoles aligned at the interface of the ferroelectric 200, forming the EDL-C′, will create an attractive force between electrons which normally repel one another, due to Coulombic repulsion. Thus, electron pairs, named Cooper pairs, are formed, which subsequently condense into a single quantum mechanical state, represented by a unique wave function. This is equivalent with macroscopic quantum coherence and can be further exemplified by the creation of the ‘supercurrent’ in the ‘gap’ material of a heterojunction like 310/200 in 50, 60, and 90, 500/200 in 70, 600/200 in 80. In the present invention, under room or higher temperature conditions, the thermal agitations (fluctuations)-induced lattice vibrations (kinetic energy) will couple with the coalescent dipoles, dipoles or ions vibrations allowing the dipoles to align even further, reducing the internal resistance to the movement of ions and/or dipoles and increasing the dielectric constant to generate a virtual ‘soup’ of fluctuations, a highly non-linear, far-from-equilibrium environment at the interface of the conductor 310 and ferroelectric 200, of semiconductor 500 and ferroelectric 200, or of superconductor 600 and ferroelectric 200.

The complex interactions between a physical system and its surroundings (environment), disrupt the quantum mechanical nature of a system and render it classical under ordinary observation. This process is known as decoherence. However, it is argued that decoherence we can be retarded (delayed) (and possibly even suppressed when the physical system is decoupled from the environment) by accelerated spin and/or accelerated vibration of electrically charged matter under rapid acceleration transients. This may be the very condition to achieve a state of macroscopic quantum coherence, the idea being that the system is not let to achieve thermodynamic equilibrium, by constantly delaying the onset of relaxation to equilibrium (hence the production of maximal entropy is delayed). The system, then, may “violently” react by generating “anomalous” emergent phenomena, such as room temperature superconductivity. If for example one of the preferred embodiments like 10 is connected to a resistor, an LED, or a diode, the thermodynamic equilibrium is retarded since a current is continuously circulating in the external circuit. At 40° C., the oscillation of electrically charged matter is observed in a ferroelectric-induced 2D superconductor feedback cell 10 to 70 and 90. At room temperature, a supercurrent can be induced during several years as experienced by us during the last five years in a feedback cell such as the embodiments 10 to 70.

The Prigogine effect as discussed in the paper, “The high energy electromagnetic field generator” published in Int. J. Space Science and Engineering, Vol. 3, No. 4, 2015, pp. 312-317, explains that under three conditions, a chaotic system (the aforementioned ‘soup’ of fluctuations) can self-organize into an orderly state, equivalent to the state of macroscopic quantum coherence. These conditions are the existence of a highly non-linear medium (as in this case a ferroelectric material), an abrupt departure far-from-thermodynamic equilibrium, and an energy flux (caused by spontaneous alignment of the dipoles and ionic conduction due to the need to align the Fermi levels of conductor 310, semiconductor 500, or superconductor 600 with conductor 320, semiconductor 500, or superconductor 610, and the ferroelectric 200 via the external circuit) to maintain the process of self-organization (order from chaos). This shows that the present invention has macroscopic quantum coherence as observed in FIG. 2, fulfilling a requirement for superconductivity. As shown, all three conditions for self-organization are met by the present invention, thus, as a result, low to higher temperature 2D superconductivity is herein established and enabled.

It is possible that the key to superconductivity is the enablement of local macroscopic quantum coherence, namely the ability of a macroscopic object to act as if quantum mechanical in nature exhibiting such phenomena as superposition, entanglement, or tunnelling. In summary, one can argue that the synthesis of two physical mechanisms, namely the Cooper effect (or bipolaron formation), and the Prigogine effect leads directly to the possibility of room to high temperature 2D superconductivity, at least in the preferred embodiments. Therefore, the supercurrent may be generated along the interface (boundary) between the conductor 310, semiconductor 500, or superconductor 600 and a ferroelectric 200.

The pyroelectric effect offers another interesting solid-state approach for harvesting ambient thermal energy to power distributed networks of sensors and actuators that are remotely located or otherwise difficult to access. There have been, however, few device-level demonstrations due to challenges in converting spatial temperature gradients into temperature oscillations necessary for pyroelectric energy harvesting.

The decoupling of phonon and electron transport is essential in Thermoelectric cells; For example, in relaxor ferroelectrics, nano-polar regions associated with intrinsic localized phonon modes provide glass-like phonon characteristics due to the large levels of phonon scattering which is highly welcome for achieving the binomial feature ‘electron-crystal phonon-glass’ for an “ideal” TE with a high figure of merit as described above in the background section.

An important inference is that the “best” Thermoelectric requires high electronic carrier concentrations, ˜10¹⁸ to ˜10²¹ cm⁻³, i.e. 10²⁰ cm⁻³, associated with high electrical conductivity. These are similar conditions to those necessary for a feedback cell to work at constant temperature. Therefore, enabling the superimposition of both the feedback and TE phenomena in an embodiment 40.

1. A feedback cell, comprising:
a high dielectric constant ferroelectric 2D superconductor or ferroelectric-metal disposed between two similar or dissimilar materials,
wherein an electrical potential difference of the cell increases during discharge with a load from below to above room temperatures.

2. The feedback cell of claim 1, wherein the ferroelectric 2D superconductor or ferroelectric-metal comprises the materials selected from the list consisting of:
R3-2yM_{y}Cli-xHalₓOi-_{z}A_{z} with (R=Li, Na, K; M=Be, Ca, Mg, Sr, and Ba; Hal=F, Br, I; A=S, Se) and 0<y<0.5, 0<x<1, and 0<z<1, R₃-3yMyCli-xHalₓOi-_{z}A_{z} with (R=Li, Na, K; M=B, Al; Hal=F, Br, I; A=S, Se) and 0<y<0.5, 0<x<1, and 0<z<1,
R3-2y-zM′yH_{z}Cli-xHalₓOi-dAd (R=Li, Na, K; M′=Be, Ca, Mg, Sr, and Ba; Hal=F, Br, I; A=S, Se) and 0<y<0.5, 0<z<2, 0<x<1, and 0<d<1,
R₃-3y-zM′_{y}H_{z}Cli-xHalxOi-dAd with 0<y<0.5, 0<z<2, 0<x<1, and 0<d<1,
a mixture of the foregoing,
a mixture of the foregoing in combination with U2S, Na2S, SiCh, Li2O, Na2O, or H2S,
and a mixture of the foregoing with a polymer, a plasticizer, or a glue.

3. The feedback cell of claim 1, wherein the ferroelectric 2D superconductor or ferroelectric-metal is in contact with one or two insulator layers.

4. (canceled)

5. (canceled)

6. The feedback cell of claim 1, wherein the ferroelectric is Na-based Na2.99Bao.oosCIO and the conductors are Cu.

7. The feedback cell of claim 6, wherein ferroelectric is the Na-based Na2.99Bao.oosCIO and the conductors are Zn and Cu.

8. The feedback cell of claim 6, wherein the ferroelectric is the Na-based Na2.99Bao.oosCIO and the conductors are Zn and C configured as a foam, a sponge, wires, nanotubes, graphene, graphite, carbon black or any other allotrope or carbon structure, with or without impurities.

9. The feedback cell of claim 1, wherein the ferroelectric is a Li-based (1-x)Li2.99Bao.oosCIO+xLi3-2y-zM_{y}H_{z}CIO, with 0<x<1, and wherein one conductor is Li and the other is a mixture of MnCh with carbon black and a binder.

10. The feedback cell of claim 6, wherein the ferroelectric is the Na-based (1-x)Na2.99Bao.oosCIO+xNa3-2y-zM_{y}H_{z}CIO, with 0<x<1 and 0<z<2, and wherein one conductor is Na and the other is a mixture of NasN\hat{ }fPC h with carbon black and a binder.

11. (canceled)

12. The feedback cell of claim 1, wherein the ferroelectric is a Li-based Li2.99Bao.oosCIO+U2S, the conductor is Al and the semiconductor Si.

13. (canceled)

14. The feedback cell of claim 1, further comprising two interfaces one being a semiconductor or a conductor, and the other being an insulator with a conductor contact or electron collector.

15. The feedback cell of claim 1, wherein the ferroelectric is Na-based, K-based, or Li-based and the conductors are selected from the list consisting of: Zn or Cu, Li, Na, a Li alloy or composite, a Na alloy or composite, and a K alloy or a composite, and wherein the ferroelectric has a surface area in contact with an insulator.

16. The feedback cell of claim 1, wherein the ferroelectric is Li-based, Li2.99Bao.oosCIO or a Li2.99Bao.oosCIO+Li3-2y-zM_{y}H_{z}CIO mixture or a composite, and wherein the conductor is Li or a Li alloy, and wherein the ferroelectric has a surface area in contact with an insulator.

17. The feedback cell of claim 1, further comprising two concentric wire conductors separated by a ferroelectric.

18. The feedback cell of claim 1, further comprising at least one interface between a ferroelectric and an insulator.

19. (canceled)

20. The feedback cell of claim 1, further comprising at least one interface between a ferroelectric and a superconductor.

21. The feedback cell of claim 1, wherein the superconductor is ZnO.

22. The feedback cell of claim 1, wherein the ferroelectric is Li, K, or Na-based and wherein the superconductors are both Al or Ti or Sn, Li and Al, or Li and Ti or Sn.

23. The feedback cell of claim 1, wherein the ferroelectric is Li, K, or Na-based and the superconductors are HgBazCazCusOx, FeSe, or H2S.

24. The feedback cell of claim 1, wherein the ferroelectric is a ferroelectric polymer-glue mixture or a ferroelectric ionic liquid mixture.

25. The feedback cell of claim 1, wherein the ferroelectric is CaCuTiCh or a composite or a mixture of the ferroelectric materials listed in claim 2.

26. (canceled)

27. (canceled)

28. (canceled)

29. (canceled)

30. (canceled)

31. (canceled)
